(19) United States
(12) Patent Application Publication
(10) Pub. No.: US 2013/0250208 A1
(43) Pub. Date: Sep. 26, 2013

(54) DISPLAY PANEL AND METHOD OF FABRICATING THE SAME

(71) Applicants: Kuan-Hsien Wu, Changhua County (TW); Chin-Feng Chung, Taichung City (TW); Hua-Te Shih, Changhua County (TW); Chih-Yuan Wang, Taichung City (TW)

(72) Inventors: Kuan-Hsien Wu, Changhua County (TW); Chin-Feng Chung, Taichung City (TW); Hua-Te Shih, Changhua County (TW); Chih-Yuan Wang, Taichung City (TW)

(73) Assignees: WINTEK CORPORATION, Taichung City (TW); Wintek (China ) Technology Ltd., Guangdong Province (CN)

(21) Appl. No.: 13/831,281

(22) Filed: Mar. 14, 2013

(30) Foreign Application Priority Data
Mar. 22, 2012 (TW) 101109874

(51) Int. Cl. H01L 51/52; H01L 51/56

(52) U.S. Cl. CPC H01L 51/52; H01L 51/56
USPC 349/61; 438/30; 257/40

(57) ABSTRACT

A display panel and a method of fabricating the same are provided. The display panel includes a first substrate, a second substrate, a first active device layer, an organic light emitting layer, and an evaporation layer. The second substrate is opposite to the first substrate. The first active device layer is disposed on the first substrate. The organic light emitting layer is disposed on the first active device layer and electrically connected to the first active device layer. The evaporation layer covers a side of the organic light emitting layer away from the first active device layer. A material of the evaporation layer includes a metal element. The evaporation layer has an oxidation surface away from the organic light emitting layer and a metal surface adjacent to the organic light emitting layer.

### CROSS-REFERENCE TO RELATED APPLICATION

This application claims the priority benefit of Taiwan application serial no. 101109874, filed on Mar. 22, 2012. The entirety of the above-mentioned patent application is hereby incorporated by reference herein and made a part of this specification.

### BACKGROUND OF THE DISCLOSURE

1. Field of the Disclosure

The invention relates to a display panel. More particularly, the invention relates to an organic light emitting display (OLED) panel.

2. Description of Related Art

An organic light emitting display panel is a self-luminescence display. The OLED panel, with the characteristics of low driving voltage, DC current driving, high brightness, high contrast, and light volume, is believed to be an important flat display panel product in the coming generation.

However, the display medium, the organic light emitting material, utilized in the OLED panel is liable to be damaged by water vapor and the like so that the lifetime of the OLED panel is significantly restricted. Particularly, in a display panel having the composite display medium formed by combining another display medium in addition to the organic light emitting material into the OLED panel, the organic light emitting material in the OLED panel is further liable to be damaged thereby.

In one instance, in a design of combining a polymer dispersed liquid crystal (PDLC) into the OLED panel, the PDLC provides particular optical characteristics for rendering the display panel have desirable display effect such as good reading comfort. Nevertheless, the PDLC and the organic light emitting material are solvable with each other so that the composite display panel can not have a prolonged lifetime owing that the organic light emitting material is easily solved by the PDLC. Accordingly, the issue that the organic light emitting material is liable to be damaged needs be overcome when another display medium is combined into the OLED panel.

### SUMMARY OF THE DISCLOSURE

The invention is directed to a display panel, wherein the display medium thereof is not liable to be damaged so as to have desirable lifetime.

The invention is also directed to a method of fabricating a display panel, wherein the material layer for protecting the display medium is fabricated by using the fabrication conditions without damaging the display medium.

The invention provides a display panel including a first substrate, a second substrate, a first active device layer, an organic light emitting layer, and an evaporation layer. The second substrate is opposite to the first substrate. The first active device layer is disposed on the first substrate. The organic light emitting layer is disposed on the first active device layer and electrically connected to the first active device layer. The evaporation layer covers a side of the organic light emitting layer away from the first active device layer. A material of the evaporation layer includes a metal element. The evaporation layer has an oxidation surface away from the organic light emitting layer and a metal surface adjacent to the organic light emitting layer.

In an embodiment of the invention, the display panel further includes a liquid crystal layer filled between the first substrate and the second substrate, wherein the liquid crystal layer is separated from the organic light emitting layer by the evaporation layer. Herein the display panel further includes a second active device layer disposed on the second substrate for driving the liquid crystal layer.

In an embodiment of the invention, the display panel further includes an electrode layer disposed between the organic light emitting layer and the evaporation layer.

In an embodiment of the invention, the metal element includes aluminum, zinc, or a combination thereof.

In an embodiment of the invention, an oxidation activity of the metal layer is not smaller than aluminum.

In an embodiment of the invention, a thickness of the evaporation layer ranged from 50 Å to 300 Å.

The invention further provides a method of fabricating a display panel. A first active device layer and an organic light emitting layer electrically connected to the first active device layer are formed on a first substrate. An evaporation process is performed for evaporating a metal element on the organic light emitting layer and subsequently an oxidation process is performed to form an evaporation layer having an oxidation surface away from the organic light emitting layer and a metal surface adjacent to the organic light emitting layer. The organic light emitting layer is packaged between the first substrate and a second substrate.

In an embodiment of the invention, the oxidation process includes performing an oxygen plasma treatment on the evaporation layer at a side away from the organic light emitting layer so that the evaporation layer is partially oxidized to have the oxidation surface.

In an embodiment of the invention, the method further includes performing an oxygen plasma treatment on the first substrate before forming the first active device layer on the first substrate.

In an embodiment of the invention, the method further includes forming an electrode layer disposed between the organic light emitting layer and the evaporation layer.

In an embodiment of the invention, the method further includes filling a liquid crystal layer between the first substrate and the second substrate, wherein the liquid crystal layer is separated from the organic light emitting layer by the evaporation layer.

In an embodiment of the invention, the method further includes forming a second active device layer on the second substrate for driving the liquid crystal layer.

In view of the above, the method according to an embodiment of the invention includes the process, such as the evaporation process, compatible to the known fabrication process of an OLED panel for forming a material layer with the protection function on an organic light emitting layer. The organic light emitting layer is prevented from being damaged by the external substances so as to have prolonged lifetime. In addition, the material layer with the protection function formed by the evaporation process has electric conductive property so as to further serve the function as an electrode layer in addition to the protection function. As such, the display panel according to an embodiment of the invention having the evaporated material layer can utilizes a lower voltage for driving the organic light emitting layer than the voltage utilized for driving the related display panel without the evaporated material layer. Alternately, the evaporated material layer can be served as the electrode for driving the organic light emitting layer.

In order to make the aforementioned properties and advantages of the invention more comprehensible, embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic view illustrating a display panel according to an embodiment of the invention.

FIGS. 2A and 2B are schematic views showing the fabrication of the evaporation layer according to an embodiment of the present invention.

FIG. 3 is a schematic view illustrating a display panel according to another embodiment of the invention.

FIG. 4 is a schematic view illustrating a display panel according to further another embodiment of the invention.

FIG. 5 is a schematic view illustrating a display panel according to another embodiment of the invention.

FIG. 6 is a schematic view showing the relationships between the driving voltage and the produced current density of a display panel according to an embodiment of the invention and a related display panel.

FIG. 7A and FIG. 7B respectively show the lighting test result of the related display panel without the evaporation layer and the lighting test result of the display panel with the evaporation according to the embodiment depicted in FIG. 5.

### DETAILED DESCRIPTION OF THE EMBODIMENTS

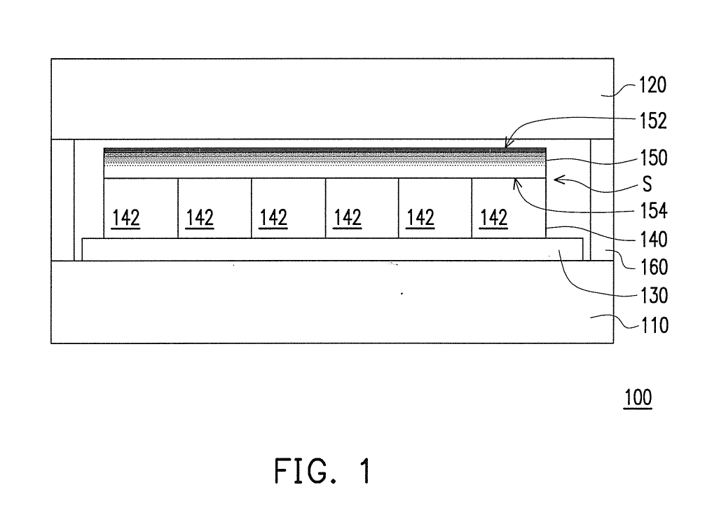

FIG. 1 is a schematic view illustrating a display panel according to an embodiment of the invention. Referring to FIG. 1, a display panel 100 includes a first substrate 110, a second substrate 120, a first active device layer 130, an organic light emitting layer 140, an evaporation layer 150 and a sealant 160. The second substrate 120 is opposite to the first substrate 110, wherein the first substrate 110 is substantially located under the second substrate 120 in the thickness direction so that the main surface of the first substrate 110 and the main surface of the second substrate 120 are not coplanar. In addition, the sealant 160 of the display panel 100 has, for example, a ring-like structure and connects the first substrate 110 with the second substrate 120 so that the first substrate 110, the second substrate 120, and the sealant 160 together define a sealed space S. In other embodiment, the second substrate 120 and the sealant 160 of the display panel 100 can be replaced be a packaging cover (not shown) so that the sealed space S can, alternately, be defined by the first substrate 110 and the packaging cover (not shown).

The first active device layer 130 is disposed on the first substrate 110 and located inside the sealed space S. The organic light emitting layer 140 is disposed on the first active device layer 130 and electrically connected to the first active device layer 130. According to the present embodiment, the organic light emitting layer 140 can be consisted of a plurality of organic light emitting units 142 arranged in an array and the first active device layer 130 can include a plurality of active devices (not shown) arranged in an array.

In general, the plurality of organic light emitting units 142 arranged in an array can be separated from one another by a wall structure (not shown) or the like. Furthermore, each organic light emitting unit 142 at least includes an organic light emitting material layer. Each organic light emitting unit 142 can be driven by a corresponding active device so as to independently emit light with particular brightness (gray level) for displaying an image. The organic light emitting units 142 constructing the organic light emitting layer 140 can include the organic light emitting units with different colors such as red organic light emitting units, green organic light emitting units, blue organic light emitting units, yellow organic light emitting units, magenta organic light emitting units, cyan organic light emitting units, or the like. That is, the display panel 100 can display colorful images.

The organic light emitting layer 140 has the light emitting function by the organic light emitting material. However, the organic light emitting material is sensitive to the external substances. In an instance, the organic light emitting material is liable to have a reaction with the water vapor in the air so as to be deteriorated. Therefore, a side of the organic light emitting layer 140 away from the first active device layer 130 is covered by the evaporation layer 150 according to the present embodiment, such that the organic light emitting material in the organic light emitting layer 140 is prevented from in contact with the water vapor in the external air, which improves the lifetime of the organic light emitting layer 140. Specifically, a material of the evaporation layer 150 includes a metal element. The evaporation layer 150 has an oxidation surface 152 away from the organic light emitting layer 140 and a metal surface 154 adjacent to the organic light emitting layer 140. Namely, the evaporation layer 150 is substantially a metal material layer formed by the evaporation process and having the oxidation surface 152.

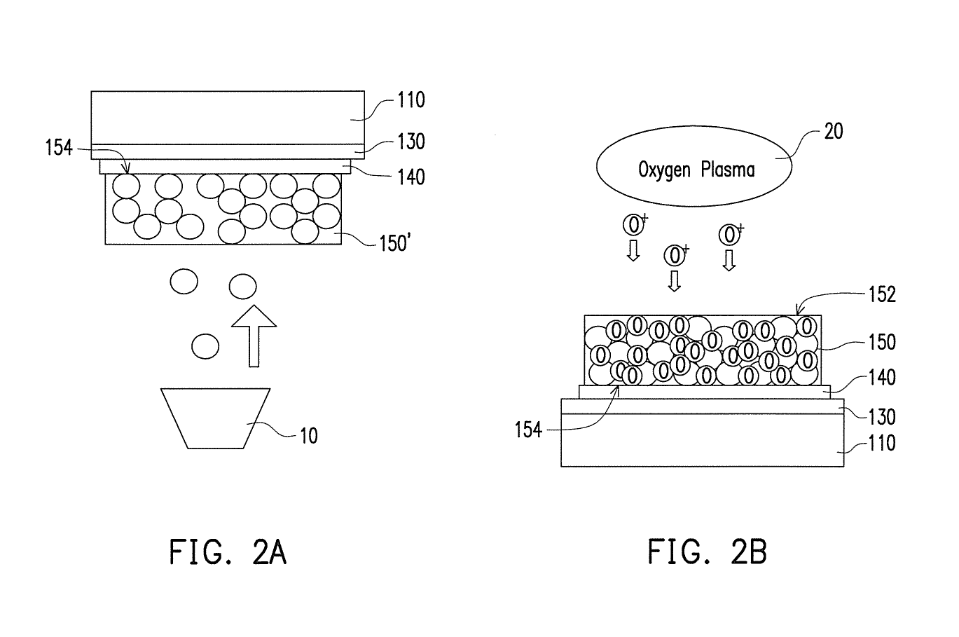

FIGS. 2A and 2B are schematic views showing the fabrication of the evaporation layer according to an embodiment of the present invention. Referring to FIG. 1, during fabricating the display panel 100, the first active device layer 130 and the organic light emitting layer 140 are sequentially formed on the first substrate 110, wherein the fabrication processes of the first active device layer 130 and the organic light emitting layer 140 can be referred to the known fabrication processes of the active device array and the organic light emitting array and are not iterated here. Now, the first substrate 110 has been formed with the first active device layer 130 and the organic light emitting layer 140 electrically connected to the first active device layer 130 thereon.

Next, referring to FIG. 1 and FIG. 2A simultaneously, an evaporation process is performed, in which the evaporation source 10 consisting of metal material is used for being evaporated so as to form an evaporation layer 150′ on the organic light emitting layer 140. In one instance, the material of the evaporation source 10 can be aluminum, zinc, or other metal material having the oxidation activity greater than (or not smaller than) aluminum. That is to say, the material of the evaporation layer 150′ mainly includes aluminum, zinc, or other metal material having the oxidation activity greater than (or not smaller than) aluminum. Nevertheless, in other embodiments, the material of the evaporation layer 150′ can be alloy such as an aluminum-zinc alloy. Generally, the fabrication process of the organic light emitting layer 140 also includes the evaporation process. Accordingly, the evaporation process as depicted in FIG. 2A is compatible to the known fabrication process of the organic light emitting layer 140, which does not require additional fabrication equipments and is not liable to damage the organic light emitting layer 140. Furthermore, by adopting the evaporation process, the first substrate 110 need not be heated and the process is performed under the room temperature, which further prevents the organic light emitting layer 140 from being deteriorated. It is noted that the evaporation source 10 utilized in the present embodiment has the material of metal material rather than metal oxide or metal nitride so that the evaporation layer 150′ has a metal surface 154 in contact with the organic light emitting layer 140.

Thereafter, referring to FIG. 2A and FIG. 2B, an oxidation process is performed, in which the oxygen plasma 20 is applied to the surface of the evaporation layer 150′ depicted in FIG. 2A so that the evaporation layer 150 having the oxidation surface 152 and the metal surface 154 as depicted in FIG. 2B and FIG. 1 is formed. That is, the oxidation process can be an oxygen plasma treatment according to the present embodiment. In general, the fabrication process of the known organic light emitting display can include the oxygen plasma treatment for a pretreatment on the substrate so that the oxidation process shown in FIG. 2B is compatible to the known process, which requires no additional fabrication equipment and can be performed under high extent vacuum state. Nevertheless, the present invention should not be construed as limited to the embodiments set forth herein. In other embodiments, to expose the evaporation layer 150′ under the environment containing oxygen can form the evaporation layer 150 having the oxidation surface 152. It is noted that the time consumption for forming the oxidation surface 152 can be changed with the adopted process so that the suitable oxidation process can be selected according to actual requirement.

Herein, the dense oxidation surface 152 can be constructed by the oxygen element combining with the metal element of the evaporation layer 150 during the oxidation process. The evaporation layer 150 can thus be the protection layer of the organic light emitting layer 140 for avoiding the damage of the organic light emitting material from the water vapor. Furthermore, the oxidation level of the evaporation layer 150 can be modified by adjusting the fabrication conditions of the oxidation process. In the present embodiment, at least the surface of the evaporation layer 150 in contact with the oxygen plasma 20 is oxidized to form the oxidation surface 152 and the other portion of the evaporation layer 150 adjacent to or in contact with the organic light emitting layer 140 is not oxidized so as to have the characteristics as a non-oxidized metal. In other words, the oxygen concentration in the evaporation layer 150 is gradually reduced from the oxidation surface 152 toward the organic light emitting layer 140 in the thickness direction.

The evaporation layer 150 can have the electric conductive property if not being oxidized. Therefore, the evaporation layer 150 can be served as the electrode electrically connected to the first active device layer 130 for driving the organic light emitting layer 140 and no additional electrode is required. Consequently, the evaporation layer 150, if not being entirely oxidized, can have both the functions of a protection layer for protecting the organic light emitting layer 140 and an electrode layer for driving the organic light emitting layer 140. However, in an alternate embodiment, an additional electrode layer can be selectively configured for driving the organic light emitting layer 140.

Before fabricating the first active device layer 130, the first substrate 110 can be treated by a surface treatment so as to have desirable surface property and mechanic characteristic. A known surface treatment includes performing an oxygen plasma treatment to the first substrate 110. Accordingly, the oxidation process depicted in FIG. 2B is compatible to the surface treatment of the first substrate 110 and no additional fabrication equipment is required. In the present embodiment, the method of forming the evaporation layer 150 on the organic light emitting layer 140 is compatible to the known fabrication process of the organic light emitting display so that the method provided in the present embodiment would not increase the cost burden in establish the required fabrication equipment and the organic light emitting layer 140 can be prevented from being deteriorated by the water vapor or other substances.

Further referring to FIG. 1, after performing the above processes for forming the evaporation layer 150, the first active device layer 130, the organic light emitting layer 140 and the evaporation layer 150 are sealed and packaged in the sealed space S defined by the first substrate 110, the second substrate 120 and the sealant 160 to form the display panel 100 of the present embodiment. As those mentioned in above, the evaporation layer 150 has the dense oxidation surface 152 so as to provide desirable protection function, which avoids the organic light emitting layer 140 from the damage of the water vapor so that the lifetime of the display panel 100 can be prolonged. In addition, the evaporation layer 150 with metal material not being completely oxidized can be served as an electrode, which is conducive to simplify the design of the display panel 100. Consequently, the display panel 100 has satisfactory quality by the configuration of the evaporation layer 150.

In one embodiment, the evaporation layer 150 is required to have sufficient light transparency when the display panel 100 displays imaged by emitting the display light outward from the second substrate 120 so that the thickness of the evaporation layer 150 can be ranged from 50 Å to 300 Å. Accordingly, even if a portion of the evaporation layer 150 is composed of non-oxidized metal material, the light emitted from the organic light emitting layer 140 can pass through the evaporation layer 150 and be emitted outward from the second substrate 120. Namely, the display panel 100 can be a top emission type OLED panel. However, in other embodiments, the display panel can be designed as a bottom emission type OLED panel or dual side emission type OLED panel.

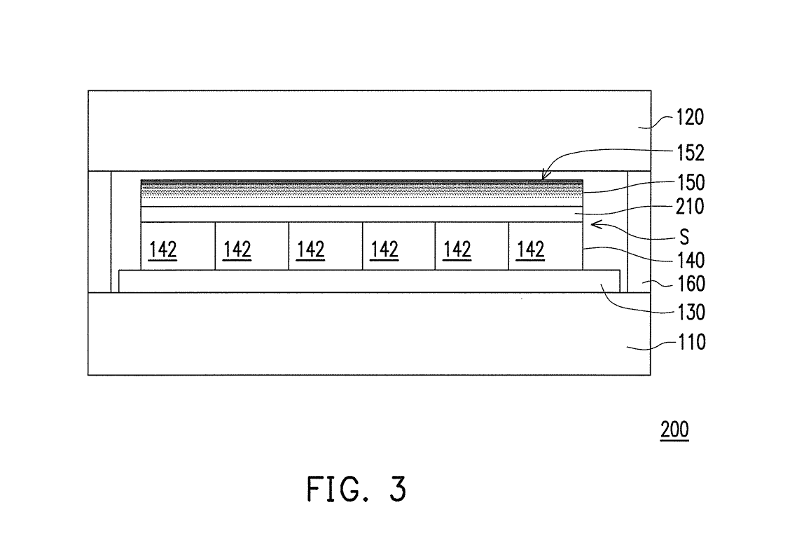

FIG. 3 is a schematic view illustrating a display panel according to another embodiment of the invention. Referring to FIG. 3, the display panel 30, substantially similar to the display panel 100 depicted in FIG. 1, is different from the display panel mainly in that the display panel 200 further include an electrode layer 210 configured between the organic light emitting layer 140 and the evaporation layer 150. The same elements of the display panel 100 and the display panel 200 are referred to the same reference number, and they are not repeated here. The material of the electrode layer 210 includes silver, magnesium, other metals, metal alloy, or non-metal conductive material such as a metal oxide. In one embodiment, the electrode layer 210 can be formed by a single conductive material layer. In another embodiment, the electrode layer 210 can be formed by stacking a plurality of conductive material layers. Herein, the evaporation layer 150 can have the electric conductive property so that the stacking of the electrode layer 210 and the evaporation layer 150 facilitates the improvement of the electric conductivity, and thereby the required driving voltage of the organic light emitting layer 140 can be reduced.

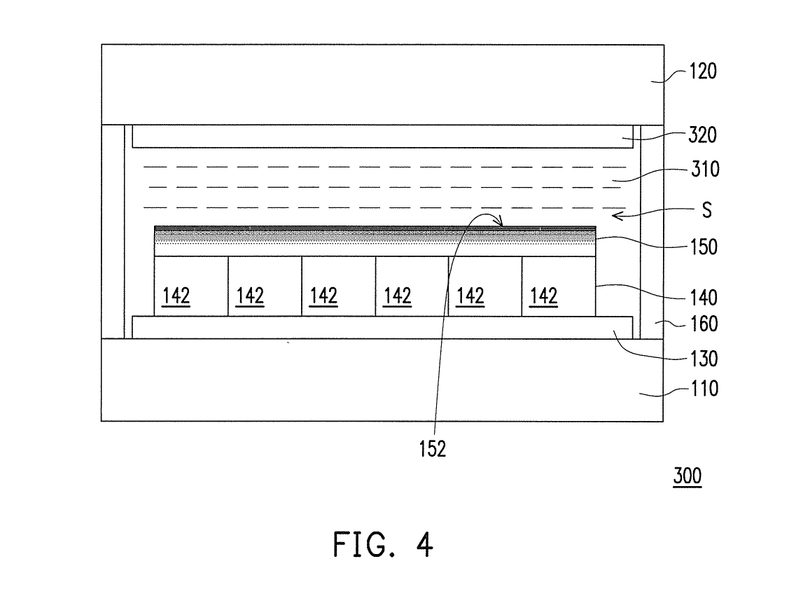

FIG. 4 is a schematic view illustrating a display panel according to further another embodiment of the invention. Referring to FIG. 4, the display panel 300 has the components of the display panel 100 and further includes a liquid crystal layer 310 and a second active device layer 320. The liquid crystal layer 310 is filled in the sealed space S defined by the first substrate 110, the second substrate 120 and the sealant 160 and is separated from the organic light emitting layer 140 at least by the evaporation layer 150. The second active device layer 320 is disposed on the second substrate 120 to drive the liquid crystal layer 310. Herein, the second active device layer 320 can be selectively combined with a color filter layer for having colorful displaying effect. Namely, the second active device layer 320 can be a design of a color filter on array (COA) layer.

In the present embodiment, the display panel 300 can display images by either the organic light emitting layer 140 or the liquid crystal layer 310, which is served as a display panel combining two display media. The material of the liquid crystal layer 310 can be PDLC so that the configuration of the liquid crystal layer 310 is conducive to improve the reading comfort, which conduces the display panel 300 suitable to be applied in the products such as electronic papers or electronic books. Certainly, the display panel 300 can be applied in any product capable of displaying images, and not restricted to be applied in the electronic paper or the electronic book.

Owing to the solvability of the organic light emitting layer 140 in the PDLC and the water content in the PDLC, the organic light emitting layer 140 is liable to be damaged by the configuration of the PDLC. The short lifetime is an issue of the display panel having the composite display medium. Nevertheless, in the present embodiment, the liquid crystal layer 310 and the organic light emitting layer 140 are separated from each other at least by the evaporation layer 150, wherein the evaporation layer 150 has the dense oxidation surface 152. Accordingly, the evaporation layer 150 avoids the solving of the organic light emitting material of the organic light emitting layer 140 in the liquid crystal layer 310, which conduces to prolong the lifetime of the display panel 300. It is noted that the liquid crystal layer 310 has no intent to be construed as a limitation of the display medium in the display panel 300. Any display medium possibly damaging the organic light emitting layer 140 separated from the organic light emitting layer 140 by the evaporation layer 150 can comply the scope of the invention.

According to the foregoing embodiments, the fabrication process of the evaporation layer 150 is compatible to the existed process so that the configuration of the evaporation layer 150 does not require additional fabrication equipment, which does not increase the fabrication cost. Furthermore, the evaporation layer 150 has the electric conductive property for serving as an electrode layer driving the organic light emitting layer 140, which simplifies the structure of the display panel 300.

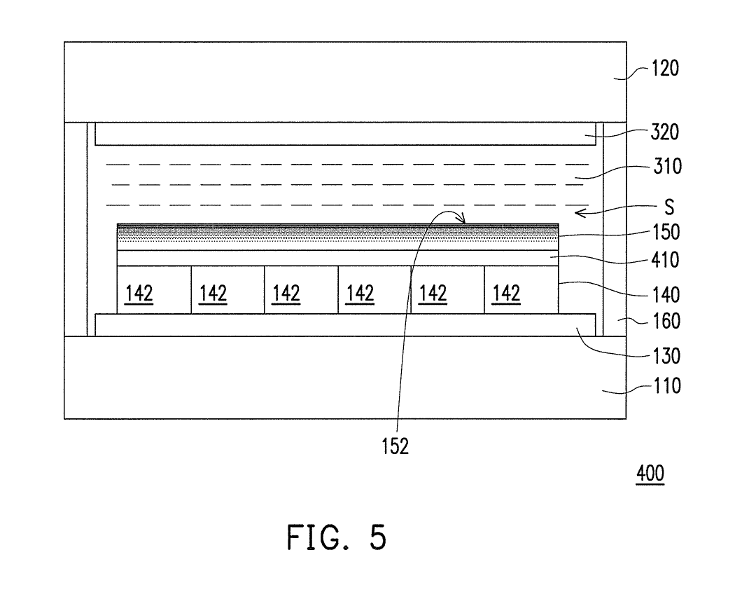

On the other hand, as shown in FIG. 5, in the display panel 400, an electrode layer 410 can be disposed between the evaporation layer 150 and the organic light emitting layer 140 so that the stacking of the evaporation layer 150 and the electrode layer 410 provides desirable conductivity. Now, the display panel 400 can be driven by a lower driving voltage.

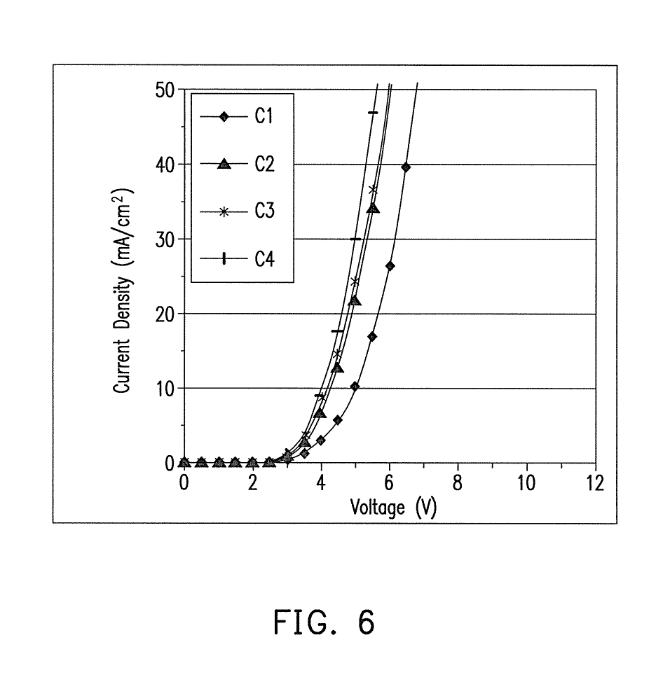

FIG. 6 is a schematic view showing the relationships between the driving voltage and the produced current density of a display panel according to an embodiment of the invention and a related display panel, wherein the two display panels both have the composite display medium design combining the liquid crystal layer and the organic light emitting material. In FIG. 6, the curve C1 represents the characteristic of a known display panel without the configuration of the evaporation layer and the curves C2, C3 and C4 represent the characteristics of the display panel with the configuration of the evaporation layer as depicted in FIG. 5, wherein the curve C2 represents the condition that the thickness of the evaporation layer in the display panel is 50 Å, the curve C3 represents the condition that the thickness of the evaporation layer in the display panel is 150 Å, and the curve C4 represents the condition that the thickness of the evaporation layer in the display panel is 300 Å.

Compared with the curve Cl, the curve C2 to the curve C4 all show that a high current density can be produced under a lower voltage. That is to say, the display panel having the characteristic of the curve C1 requires relative larger driving voltage and the display panel having the characteristic of any of the curves C1, C2, and C3 requires relative small driving voltage. It is clear that the stacking of the evaporation layer 150 and the electrode layer 410 on the organic light emitting layer 140 conduces to reduce the driving voltage of the display panel 400.

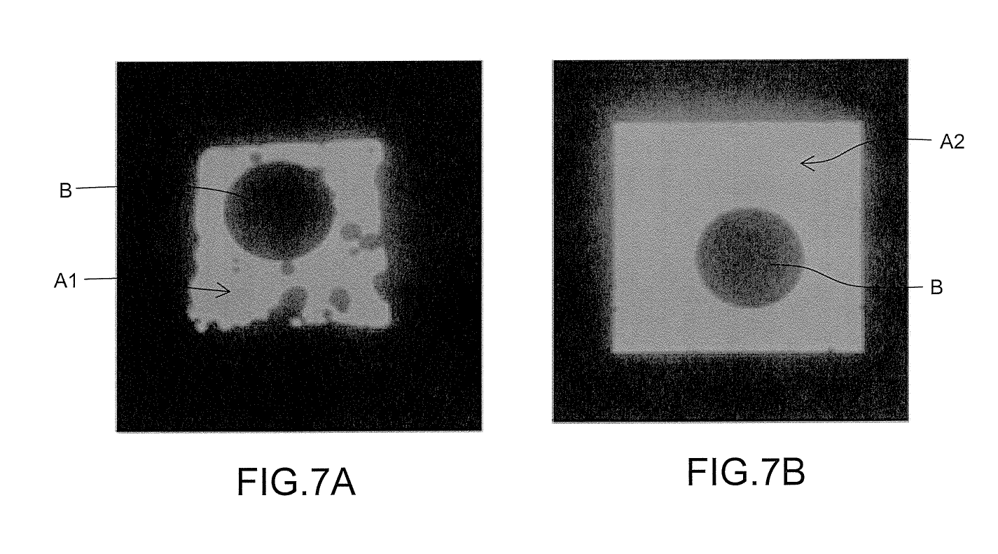

FIG. 7A and FIG. 7B respectively show the lighting test result of the related display panel without the evaporation layer and the lighting test result of the display panel with the evaporation layer fabricated by the method according to the embodiment depicted in FIG. 5. The lighting area A1 and A2 are shown in FIG. 7A and FIG. 7B, while the dark spot B therein is the image of the testing probe and is not related to the lighting effect of the display panel. FIG. 7A shows poor display quality (the light area A1 is not complete) owing that the display medium is damaged. On the contrary, FIG. 7B shows good display quality (the light area A1 is not complete) owing that the display medium is not damaged. Based on those shown in FIG. 7A and FIG. 7B, the evaporation layer configured in the embodiments of the invention provides effective protection function to the organic light emitting layer and helps to prolong the lifetime of the display panel.

In light of foregoing, an evaporation process is adopted for forming an evaporation layer covering the organic light emitting layer according to the invention and the evaporation layer has an oxidation surface. Herein, the evaporation layer is dense so that the organic light emitting layer can be protected from being damaged so as to prolong the lifetime of the display panel. Therefore, the display panel according to the invention combining the display mediums, such as the liquid crystal material and the organic light emitting material, the organic light emitting material can be protected by the evaporation layer from being damaged by the liquid crystal material. In addition, the material layer with the protection function formed by the evaporation process has electric conductive property so as to further provide the function as an electrode layer. As such, the display panel according to an embodiment of the invention can utilizes a voltage for driving the organic light emitting layer lower than the driving voltage of the display panel without the evaporation layer. Alternately, the evaporated material layer can be served as the electrode for driving the organic light emitting layer. Furthermore, in the embodiment of the invention, the fabrication process of the evaporation layer is compatible to the known fabrication processes of the OLED panel so that the organic light emitting layer is not damaged owing to the fabrication of the evaporation layer, which improves the yield rate of fabricating the display panel and no additional fabrication equipment is needed.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A display panel, comprising:
a first substrate;
a second substrate opposite to the first substrate;
a first active device layer disposed on the first substrate;
an organic light emitting layer disposed on the first active device layer and electrically connected to the first active device layer; and
an evaporation layer covering a side of the organic light emitting layer away from the active device layer, and a material of the evaporation layer comprising a metal element, wherein the evaporation layer has an oxidation surface away from the organic light emitting layer and a metal surface adjacent to the organic light emitting layer.

2. The display panel as claimed in claim 1, further comprising a liquid crystal layer filled between the first substrate and the second substrate and a second active device layer disposed on the second substrate for driving the liquid crystal layer, wherein the liquid crystal layer is separated from the organic light emitting layer by the evaporation layer.

3. The display panel as claimed in claim 1, further comprising an electrode layer disposed between the organic light emitting layer and the evaporation layer.

4. The display panel as claimed in claim 1, wherein the metal element comprises aluminum, zinc, or a combination thereof.

5. The display panel as claimed in claim 1, wherein an oxidation activity of the metal element is not smaller than aluminum.

6. The display panel as claimed in claim 1, wherein a thickness of the evaporation layer ranges from about 50 Å to about 300 Å.

7. A method of fabricating a display panel, comprising:
forming a first active device layer and an organic light emitting layer electrically connected to the first active device layer on a first substrate;
performing an evaporation process evaporating a metal element on the organic light emitting layer and subsequently performing an oxidation process to form an evaporation layer having an oxidation surface away from the organic light emitting layer and a metal surface adjacent to the organic light emitting layer; and
packaging the organic light emitting layer between the first substrate and a second substrate.

8. The method of fabricating the display panel as claimed in claim 7, wherein the oxidation process comprises performing an oxygen plasma treatment at a side of the evaporation layer away from the organic light emitting layer so that the evaporation layer is partially oxidized to have the oxidation surface.

9. The method of fabricating the display panel as claimed in claim 7, further comprising performing an oxygen plasma treatment on the first substrate before forming the first active device layer on the first substrate.

10. The method of fabricating the display panel as claimed in claim 7, further comprising forming an electrode layer disposed between the organic light emitting layer and the evaporation layer.

11. The method of fabricating the display panel as claimed in claim 7, further comprising forming a liquid crystal layer filled between the first substrate and the second substrate and forming a second active device layer disposed on the second substrate for driving the liquid crystal layer, wherein the liquid crystal layer is separated from the organic light emitting layer at least by the evaporation layer.
